(19) United States
(12) Patent Application Publication
(10) Pub. No.: US 2026/0079274 A1
(43) Pub. Date: Mar. 19, 2026

(54) INTELLIGENT SUBSURFACE SYSTEMS AND METHODS FOR THE SAME

(71) Applicant: Schlumberger Technology Corporation, Sugar Land, TX (US)

(72) Inventors: Anatoly Aseev, Menlo Park, CA (US); Priya Mishra, Menlo Park, CA (US); Jagan Gottimukkula, Menlo Park, CA (US); Naveen Gupta, Menlo Park, CA (US); Prateek Srivastava, Menlo Park, CA (US)

(21) Appl. No.: 19/326,346

(22) Filed: Sep. 11, 2025

Related U.S. Application Data
(60) Provisional application No. 63/694,291, filed on Sep. 13, 2024.

(51) Int. Cl. G01V 1/34; G06F 16/338; G06F 16/383; G06F 16/387; G06F 16/583; G06F 30/20

(52) U.S. Cl. CPC G01V 1/34; G06F 16/338; G06F 16/383; G06F 16/387; G06F 16/583; G06F 30/20

(57) ABSTRACT

A method for search and retrieval of subsurface data of a geological region includes receiving input data related to the geological region. The method also includes generating a plurality of seismic data-text pairs based on the input data. The method also includes training an intelligence model based on the plurality of seismic data-text pairs. The method also includes generating a database using the intelligence model. The method also includes receiving an input query including a seismic data query, a text query, an image query, or a combination thereof. The method also includes generating an output from the database using the intelligence model and based on the input query.

### CROSS-REFERENCE TO RELATED APPLICATIONS

This application claims priority to and the benefit of U.S. Provisional Ser. No. 63/694,291 filed on Sep. 13, 2024, the entirety of which is incorporated herein by reference to the extent consistent with the present disclosure.

### BACKGROUND

As the exploration and extraction of hydrocarbons from underground reservoirs expands to incorporate modern technology, greater efficiency, accuracy, and safety may be achieved. The utilization of multiple different modalities to gather information about various aspects of hydrocarbon exploration and extraction over time has provided greater volumes of data. However, the evaluation of such voluminous amounts of data may present challenges to render practical improvements in yields.

With some subsurface exploration systems, developing accurate models of the formations and possibility of present hydrocarbons is paramount. Indeed, some sophisticated models may be visual and allow for relatively elaborate understanding of underground content. Yet, the modeling of subsurface measurements may not provide accurate interpretations of sensed data in some domains, such as energy development and geoscience. Accordingly, there is a continued industry goal of providing subsurface analysis systems that provide more accurate interpretations of sensed data.

### SUMMARY

A method for search and retrieval of subsurface data of a geological region is disclosed. The method includes receiving input data related to the geological region. The method also includes generating a plurality of seismic data-text pairs based on the input data. The method also includes training an intelligence model based on the plurality of seismic data-text pairs. The method also includes generating a database using the intelligence model. The method also includes receiving an input query including a seismic data query, a text query, an image query, or a combination thereof. The method also includes generating an output from the database using the intelligence model and based on the input query.

A computing system is also disclosed. The computing system includes one or more processors and a method system. The method system includes one or more non-transitory computer-readable media storing instructions that, when executed by at least one of the one or more processors, cause the computing system to perform operations for search and retrieval of subsurface data of a geological region. The operations include receiving input data including accumulated data related to the geological region. The operations also include generating a plurality of seismic data-text pairs based on the input data. Each seismic data-text pair of the plurality of seismic data-text pairs includes seismic data and generated text associated with the seismic data. The operations also include training an intelligence model based on a relationship between the respective seismic data and the respective generated text for each seismic data-text pair of the plurality of seismic data-text pairs. The operations also include generating a database using the intelligence model. The operations also include receiving an input query including a seismic data query, a text query, an image query, or a combination thereof. The operations also include generating an output from the database using the intelligence model and based on the input query.

A non-transitory computer-readable medium is also disclosed. The medium stores instructions that, when executed by one or more processors of a computing system, cause the computing system to perform operations for search and retrieval of subsurface data or a geological region. The operations include receiving input data including accumulated data related to the geological region. The operations also include generating a plurality of seismic data-text pairs based on the input data. Each seismic data-text pair of the plurality of seismic data-text pairs includes seismic data and generated text associated with the seismic data. Generating the plurality of seismic data-text pairs includes generating the seismic data for the plurality of seismic data-text pairs based on the input data. The seismic data includes synthetic seismic data, real seismic data, or a combination thereof. The synthetic seismic data is generated using a simulation based on user defined inputs. The operations further include training an intelligence model based on the plurality of seismic data-text pairs. Training the intelligence model includes training an encoder/decoder of the intelligence model based on the plurality of seismic data-text pairs to produce a trained encoder/decoder. The operations also include generating a database using the trained encoder/decoder of the intelligence model. The operations also include receiving an input query including a seismic data query, a text query, an image query, or a combination thereof. The operations also include generating an output from the database using the trained encoder/decoder of the intelligence model and based on the input query.

It will be appreciated that this summary is intended merely to introduce some aspects of the present methods, systems, and media, which are more fully described and/or claimed below. Accordingly, this summary is not intended to be limiting.

### BRIEF DESCRIPTION OF THE DRAWINGS

The accompanying drawings, which are incorporated in and constitute a part of this specification, illustrate embodiments of the present teachings and together with the description, serve to explain the principles of the present teachings. In the figures:

FIG. 1 illustrates an example of a system that includes various management components to manage various aspects of a geologic environment, according to an embodiment.

FIG. 2 illustrates a flowchart of a method interpreting subsurface data in accordance with various embodiments.

FIG. 3 illustrates aspects of a subsurface system operated in accordance with an embodiment.

FIG. 4 illustrates portions of a subsurface system conducting assorted embodiments of the present disclosure.

FIG. 5 illustrates an example of aspects of a subsurface system that may be utilized with a geologic region, according to an embodiment.

FIG. 6 illustrates portions of an example subsurface system employing various embodiments of the present disclosure.

FIG. 7 illustrates aspects of an example subsurface system, according to an embodiment.

FIG. 8 illustrates portions of an example subsurface system operated in accordance with some embodiments.

FIG. 9 illustrates a flowchart of aspects of an example subsurface system, according to an embodiment.

FIG. 10 illustrates a flowchart of portions of an example subsurface system, according to an embodiment.

FIG. 11 illustrates a flowchart of a method for search and retrieval of subsurface data of a geological region, according to an embodiment.

FIG. 12 illustrates a schematic view of a computing system for performing at least a portion of the method(s) described herein, according to an embodiment.

### DETAILED DESCRIPTION

Reference will now be made in detail to embodiments, examples of which are illustrated in the accompanying drawings and figures. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, components, circuits, and networks have not been described in detail so as not to unnecessarily obscure aspects of the embodiments.

It will also be understood that, although the terms first, second, etc. may be used herein to describe various elements, these elements should not be limited by these terms. These terms are only used to distinguish one element from another. For example, a first object or step could be termed a second object or step, and, similarly, a second object or step could be termed a first object or step, without departing from the scope of the present disclosure. The first object or step, and the second object or step, are both, objects or steps, respectively, but they are not to be considered the same object or step.

The terminology used in the description herein is for the purpose of describing particular embodiments and is not intended to be limiting. As used in this description and the appended claims, the singular forms “a,” “an” and “the” are intended to include the plural forms as well, unless the context clearly indicates otherwise. It will also be understood that the term “and/or” as used herein refers to and encompasses any possible combinations of one or more of the associated listed items. It will be further understood that the terms “includes,” “including,” “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Further, as used herein, the term “if” may be construed to mean “when” or “upon” or “in response to determining” or “in response to detecting,” depending on the context.

Attention is now directed to processing procedures, methods, techniques, and workflows that are in accordance with some embodiments. Some operations in the processing procedures, methods, techniques, and workflows disclosed herein may be combined and/or the order of some operations may be changed.

### System Overview

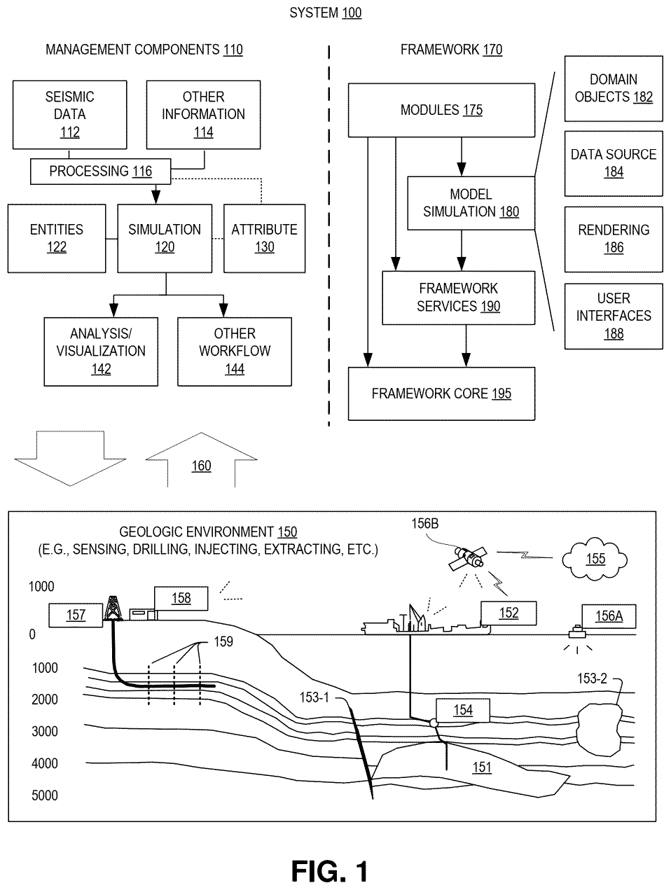

FIG. 1 illustrates an example of a system 100 that includes various management components 110 to manage various aspects of a geologic environment 150 (e.g., an environment that includes a sedimentary basin, a reservoir 151, one or more faults 153-1, one or more geobodies 153-2, etc.). For example, the management components 110 may allow for direct or indirect management of sensing, drilling, injecting, extracting, etc., with respect to the geologic environment 150. In turn, further information about the geologic environment 150 may become available as feedback 160 (e.g., optionally as input to one or more of the management components 110).

In the example of FIG. 1, the management components 110 include a seismic data component 112, an additional information component 114 (e.g., well/logging data), a processing component 116, a simulation component 120, an attribute component 130, an analysis/visualization component 142 and a workflow component 144. In operation, seismic data and other information provided per the components 112 and 114 may be input to the simulation component 120.

In an example embodiment, the simulation component 120 may rely on entities 122. Entities 122 may include earth entities or geological objects such as wells, surfaces, bodies, reservoirs, etc. In the system 100, the entities 122 may include virtual representations of actual physical entities that are reconstructed for purposes of simulation. The entities 122 may include entities based on data acquired via sensing, observation, etc. (e.g., the seismic data 112 and other information 114). An entity may be characterized by one or more properties (e.g., a geometrical pillar grid entity of an earth model may be characterized by a porosity property). Such properties may represent one or more measurements (e.g., acquired data), calculations, etc.

In an example embodiment, the simulation component 120 may operate in conjunction with a software framework such as an object-based framework. In such a framework, entities may include entities based on pre-defined classes to facilitate modeling and simulation. A commercially available example of an object-based framework is the MICROSOFT®. NET® framework (Redmond, Washington), which provides a set of extensible object classes. In the. NET® framework, an object class encapsulates a module of reusable code and associated data structures. Object classes may be used to instantiate object instances for use in by a program, script, etc. For example, borehole classes may define objects for representing boreholes based on well data.

In the example of FIG. 1, the simulation component 120 may process information to conform to one or more attributes specified by the attribute component 130, which may include a library of attributes. Such processing may occur prior to input to the simulation component 120 (e.g., consider the processing component 116). As an example, the simulation component 120 may perform operations on input information based on one or more attributes specified by the attribute component 130. In an example embodiment, the simulation component 120 may construct one or more models of the geologic environment 150, which may be relied on to simulate behavior of the geologic environment 150 (e.g., responsive to one or more acts, whether natural or artificial). In the example of FIG. 1, the analysis/visualization component 142 may allow for interaction with a model or model-based results (e.g., simulation results, etc.). As an example, output from the simulation component 120 may be input to one or more other workflows, as indicated by a workflow component 144.

As an example, the simulation component 120 may include one or more features of a simulator such as the ECLIPSE™ reservoir simulator (SLB, Houston Texas), the INTERSECT™ reservoir simulator (SLB, Houston Texas), etc. As an example, a simulation component, a simulator, etc. may include features to implement one or more meshless techniques (e.g., to solve one or more equations, etc.). As an example, a reservoir or reservoirs may be simulated with respect to one or more enhanced recovery techniques (e.g., consider a thermal process such as SAGD, etc.).

As an example, the simulation component 120 may include one or more features of a simulator such as SYMMETRY™ software (SLB, Houston, Texas). More particularly, SYMMETRY™ may process workflows in a single integrated environment with accurate thermodynamic fluid representation and consistent modeling across multiple disciplines including process, production, and HSE. The simulator integrates steady-state and transient (e.g., dynamic) analyses that may be tailored for each domain. This approach enables users to optimize processes in upstream, midstream, and downstream sectors while maximizing profits and minimizing capital expenditures. It may also help reduce emissions, energy consumption, and waste.

As an example, the simulation component 120 may include one or more features of a simulator such as PIPESIM™ (SLB, Houston, Texas). More particularly, PIPESIM™ is steady-state multiphase flow simulator that incorporates the three areas of flow modeling: multiphase flow, heat transfer and fluid behavior.

As an example, the simulation component 120 may include one or more features of a simulator such as OLGA™ (SLB, Houston, Texas). More particularly, OLGA™ is a dynamic multiphase flow simulator that models transient flow (e.g., time-dependent behaviors) to maximize production potential. Transient modeling is a component for feasibility studies and field development design. Dynamic simulation is useful in deep water and is used in both offshore and onshore developments to investigate transient behavior in pipelines and wellbores. Transient simulation with the OLGA™ simulator provides an added dimension to steady-state analysis by predicting system dynamics, such as time-varying changes in flow rates, fluid compositions, temperature, solids deposition, and operational changes.

In an example embodiment, the management components 110 may include features of a commercially available framework such as the PETREL® seismic to simulation software framework (SLB, Houston, Texas). The PETREL® framework provides components that allow for optimization of exploration and development operations. The PETREL® framework includes seismic to simulation software components that may output information for use in increasing reservoir performance, for example, by improving asset team productivity. Through use of such a framework, various professionals (e.g., geophysicists, geologists, and reservoir engineers) may develop collaborative workflows and integrate operations to streamline processes. Such a framework may be considered an application and may be considered a data-driven application (e.g., where data is input for purposes of modeling, simulating, etc.).

In an example embodiment, various aspects of the management components 110 may include add-ons or plug-ins that operate according to specifications of a framework environment. For example, a commercially available framework environment marketed as the OCEAN® framework environment (SLB, Houston, Texas) allows for integration of add-ons (or plug-ins) into a PETREL® framework workflow. The OCEAN® framework environment leverages. NET® tools (Microsoft Corporation, Redmond, Washington) and offers stable, user-friendly interfaces for efficient development. In an example embodiment, various components may be implemented as add-ons (or plug-ins) that conform to and operate according to specifications of a framework environment (e.g., according to application programming interface (API) specifications, etc.).

FIG. 1 also shows an example of a framework 170 that includes a model simulation layer 180 along with a framework services layer 190, a framework core layer 195 and a modules layer 175. The framework 170 may include the commercially available OCEAN® framework where the model simulation layer 180 is the commercially available PETREL® model-centric software package that hosts OCEAN® framework applications. In an example embodiment, the PETREL® software may be considered a data-driven application. The PETREL® software may include a framework for model building and visualization.

As an example, a framework may include features for implementing one or more mesh generation techniques. For example, a framework may include an input component for receipt of information from interpretation of seismic data, one or more attributes based at least in part on seismic data, log data, image data, etc. Such a framework may include a mesh generation component that processes input information, optionally in conjunction with other information, to generate a mesh.

In the example of FIG. 1, the model simulation layer 180 may provide domain objects 182, act as a data source 184, provide for rendering 186 and provide for various user interfaces 188. Rendering 186 may provide a graphical environment in which applications may display their data while the user interfaces 188 may provide a common look and feel for application user interface components.

As an example, the domain objects 182 may include entity objects, property objects and optionally other objects. Entity objects may be used to geometrically represent wells, surfaces, bodies, reservoirs, etc., while property objects may be used to provide property values as well as data versions and display parameters. For example, an entity object may represent a well where a property object provides log information as well as version information and display information (e.g., to display the well as part of a model).

In the example of FIG. 1, data may be stored in one or more data sources (or data stores, generally physical data storage devices), which may be at the same or different physical sites and accessible via one or more networks. The model simulation layer 180 may be configured to model projects. As such, a particular project may be stored where stored project information may include inputs, models, results and cases. Thus, upon completion of a modeling session, a user may store a project. At a later time, the project may be accessed and restored using the model simulation layer 180, which may recreate instances of the relevant domain objects.

In the example of FIG. 1, the geologic environment 150 may include layers (e.g., stratification) that include a reservoir 151 and one or more other features such as the fault 153-1, the geobody 153-2, etc. As an example, the geologic environment 150 may be outfitted with any of a variety of sensors, detectors, actuators, etc. For example, equipment 152 may include communication circuitry to receive and to transmit information with respect to one or more networks 155. Such information may include information associated with downhole equipment 154, which may be equipment to acquire information, to assist with resource recovery, etc. Other equipment 156 may be located remote from a well site and include sensing, detecting, emitting or other circuitry. Such equipment may include storage and communication circuitry to store and to communicate data, instructions, etc. As an example, one or more satellites may be provided for purposes of communications, data acquisition, etc. For example, FIG. 1 shows a satellite in communication with the network 155 that may be configured for communications, noting that the satellite may additionally or instead include circuitry for imagery (e.g., spatial, spectral, temporal, radiometric, etc.).

FIG. 1 also shows the geologic environment 150 as optionally including equipment 157 and 158 associated with a well that includes a substantially horizontal portion that may intersect with one or more fractures 159. For example, consider a well in a shale formation that may include natural fractures, artificial fractures (e.g., hydraulic fractures) or a combination of natural and artificial fractures. As an example, a well may be drilled for a reservoir that is laterally extensive. In such an example, lateral variations in properties, stresses, etc. may exist where an assessment of such variations may assist with planning, operations, etc. to develop a laterally extensive reservoir (e.g., via fracturing, injecting, extracting, etc.). As an example, the equipment 157 and/or 158 may include components, a system, systems, etc. for fracturing, seismic sensing, analysis of seismic data, assessment of one or more fractures, etc.

As mentioned, the system 100 may be used to perform one or more workflows. A workflow may be a process that includes a number of worksteps. A workstep may operate on data, for example, to create new data, to update existing data, etc. As an example, a may operate on one or more inputs and create one or more results, for example, based on one or more algorithms. As an example, a system may include a workflow editor for creation, editing, executing, etc. of a workflow. In such an example, the workflow editor may provide for selection of one or more pre-defined worksteps, one or more customized worksteps, etc. As an example, a workflow may be a workflow implementable in the PETREL® software, for example, that operates on seismic data, seismic attribute(s), etc. As an example, a workflow may be a process implementable in the OCEAN® framework. As an example, a workflow may include one or more worksteps that access a module such as a plug-in (e.g., external executable code, etc.).

### AI Powered Subsurface System

Technological advancements in the use of sensing systems have opened opportunities for businesses and individual creators, particularly when paired with machine learning (ML) and artificial intelligence (AI). That is, the power of AI assistants has allowed users to revolutionize their approaches to creating content and significantly increased the productivity and efficiency of their day-to-day operations in a variety of different industries.

Although generative AI systems may depict excellent capabilities in the general domain, such systems do not, typically, generalize well to specific domains, such as subsurface energy development and geoscience. As such, various embodiments are directed to a subsurface system that leverages a set of vision-language ML models along with AI to allow users to interact with subsurface data in a convenient and semantically plausible way, including, but not limited to, knowledge retrieval from subsurface models or geochemical and geosciences (G&G) data question answering.

Embodiments of a subsurface system may utilize AI to facilitate, and enrich, subsurface user workflows in subsurface data processing and interpretation, which may spurn the development of exploration ideas and subsurface modeling. A subsurface system may encapsulate the latest vision-language models trained on domain-specific datasets. In some embodiments, subsurface domain experts may interact with the AI subsurface assistant using a semantically plausible way, which may be similar to how the general public uses GPT-4 or Gemini technologies. As a result, subsurface data and measurements may be more intelligently manipulated, created, analyzed, and extracted to provide enhanced knowledge of subsurface content.

As a non-limiting example, AI may power a subsurface system to extract knowledge from subsurface data, such as using the current seismic cube to show two dimensional slices with direct hydrocarbon indicators (DHI) or extracting inlines with a low level of noise for further interpretation. An AI powered subsurface system may additionally answer geological data questions, such as a number of faults, location of an anticline closure, or characterizing seismic facies. Various embodiments of a subsurface system may utilize AI to provide subsurface model captioning, such as generating a caption for a subsurface model that may be subsequently reported. A text prompt from a domain expert may also be employed by a subsurface system, in some embodiments, to generate data, such as creation of a high-frequency seismic section with two faults crossing an anticline.

In accordance with assorted embodiments, an AI powered multi-modal subsurface system may have generative AI models along with data operations and machine learning operations, such as DataOps and MLOps. The generative AI component of the subsurface system may outline machine learning models, use cases for the subsurface domain, data procedures, and training procedures. It is contemplated that DataOps and MLOps aspects may demonstrate backend ML system design, the dataflow during inference time, and general backend architecture.

A subsurface system powered by AI may be directed at utilizing trained subsurface vision-language foundation AI models that can be used in various vision-language tasks, such as image-text retrieval, image captioning, vision question answering, or vision model generation with a text prompt. Such a subsurface system has many possible use cases, which can be collected under the umbrella of a so-called “talk-to-my-data” set of models. Subsurface domain experts may, in some embodiments, interact with the AI subsurface assistant using a semantically plausible way, which may be similar to how the general public uses GPT-4 or Gemini, and, as a result, subsurface data and measurements may be manipulated, created, analyzed, and extracted for knowledge.

It is noted that a subsurface system can be used for subsurface seismic images. However, the machine learning components of the subsurface system may potentially be trained to be utilized in other subsurface subdomains, such as three-dimensional geological models, well measurements, velocity models, three-dimensional reservoir models, and many others. Some embodiments of a subsurface system utilize Vision Language Models (VLMs) divided into two broad categories: a. Text-to-image, when a user creates a visual representation of subsurface data with features described in a prompt, and b. Image-to-text, when a user extracts information from visual data as text description or question-answering.

### Exemplary Method

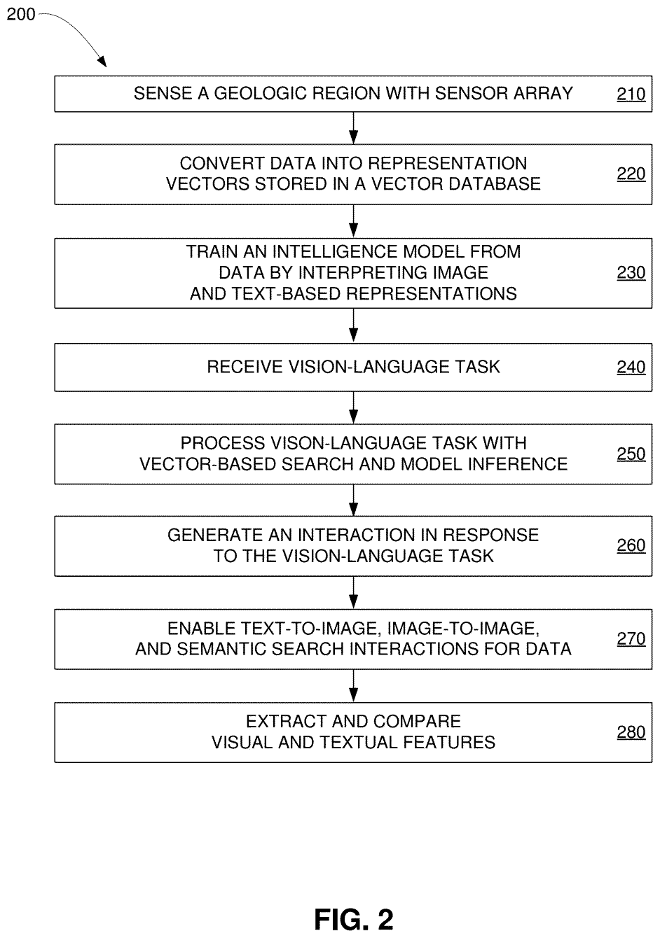

FIG. 2 illustrates a flowchart of a method 200 for interpreting subsurface readings, according to an embodiment. An illustrative order of the method 200 is provided below; however, one or more portions of the method 200 may be performed in a different order, simultaneously, repeated, or omitted. At least a portion of the method 200 may be performed using a computing system.

The method 200 may include sensing a geologic region with a sensor array to accumulate data in step 210 before the accumulated data is converting into representation vectors and stored in a vector database for efficient retrieval and processing in step 220. Next, step 230 utilizes a processor of a computing system to train an intelligence model from the accumulated data by interpreting both image and text-based representations of the accumulated data as semantically aligned streams.

In step 240, a vision-language task may be received that relates to the accumulated data and the processor proceeds to process the vision-language task, in step 250, by utilizing vector-based search and model inference to extract information from the accumulated data. An interaction may then be generated in step 260 in response to the vision-language task to provide insights about the geologic region, that were not directly present in the accumulated data. The method 200 may then enable image-to-image, text-to-image, and semantic search interactions for the accumulated data in step 270 by employing contrastive learning, with the processor, before extracting and comparing visual and textual features in a semantically meaningful way in step 280.

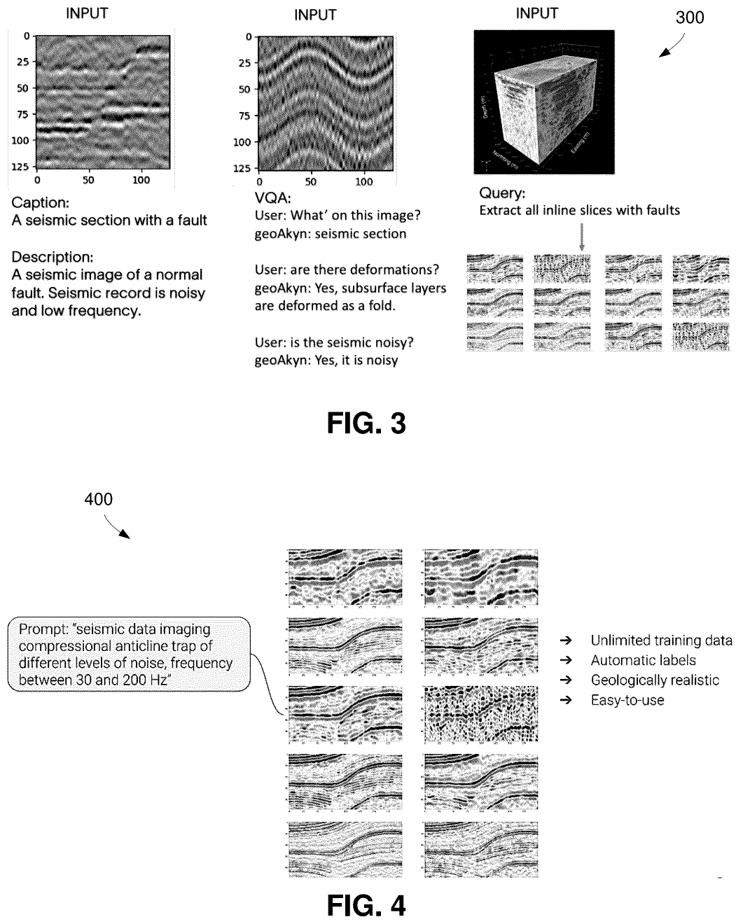

FIG. 3 illustrates a non-limiting use case 300 for operation of a subsurface system performing in accordance with various embodiments. A subsurface image captioning and descriptions may be conveyed with image inputs, which may be characterized as image-to-text. The image-to-text capabilities of a subsurface system may further allow for visual question answering (VQA) as well as data retrieval from textual queries, as shown. It is noted that the respective aspects of the subsurface system conveyed in FIG. 3 are simplified, but would be understood as capabilities with a subsurface image. However, other embodiments use text input to generate one or more images, which may be characterized as text-to-image and data generation using semantically plausible processes.

Subsurface characterization, including seismic data QC, processing, and interpretation, may be a visual task where users commonly spend a significant amount of time screening large volumes of seismic data looking for specific visual features that may be important for further seismic interpretation or important decisions. For example, some seismic data includes a multitude of seismic surveys (2D and 3D) acquired across different petroleum basins. To start seismic interpretation, users skim tens of three dimensional seismic cubes to understand their quality, which is quite labor intensive. Such intensive work may be mitigated by embodiments of the subsurface system employing AI to identify seismic sections with low noise levels or other vital characteristics. As a result, seismic sections may be provided to a seismic interpreter in response to a prompt of “show seismic sections with low noise. ”

FIG. 4 illustrates a non-limiting use case 400 for operation of a subsurface system performing in accordance with some embodiments. In response to a prompt, as shown, the subsurface system may output one or more images. Another example of operation of a subsurface system returns desired features using a semantically plausible prompt to a seismic interpreter in response to a prompt for a specific structural, or stratigraphic, feature on a three-dimensional seismic cube that is important for petroleum exploration.

The text-to-image capabilities of a subsurface system contrast to traditional workflow that may use the “intersection player” in the Petrel interpretation window before clicking the “Next” button to visualize the two-dimensional slice in a specified direction, which is then used to look for a specific seismic record that characterizes a desired feature. This workflow is cumbersome and time-consuming. As such, the subsurface system can identify seismic sections with the desired feature using the semantically plausible prompt, such as “show seismic slices with DHIs” or “show seismic slices with a fault dipping east.”

Another example of subsurface system operation is a conversation with data and data question answering. It is noted that even experienced domain experts need assistance in understanding subsurface datasets, and this is even more applicable to non-experts. One such conversational feature of a subsurface system allows for questions about the seismic images, like “How many subsurface faults do you see?” or “Explain a possible depositional environment given these seismic facies,” to result in practical answers. In another example of subsurface system operation, domain experts, especially consultants, may create presentations and reports that are supplemented with automatic captioning of a subsurface image or creating a paragraph of text describing observed seismic features.

Although the abovementioned examples relate to seismic data, the subsurface system can be used for other subsurface types of data and measurements depending on the availability of training data. Returning to FIG. 4, the subsurface system may generate meaningful and physically correct subsurface models (or data) using semantically plausible ways. Firstly, a subsurface system can generate unlimited, geologically realistic, and automatically labeled datasets that can be applied to other AI model training. Secondly, the subsurface system can be leveraged for educational purposes and training courses, facilitating an intuitive linkage between geological concepts and corresponding subsurface models for users. Thirdly, the framework of a subsurface system can provide visual aids and insights in exploration meetings for better decision-making. In addition, the subsurface system can generate missing data, in some embodiments, using text prompts. Finally, such multimodal models can bridge the link between text and images in a reverse way, supporting a use case of specific feature extraction.

### AI Machine Learning Models for Subsurface System

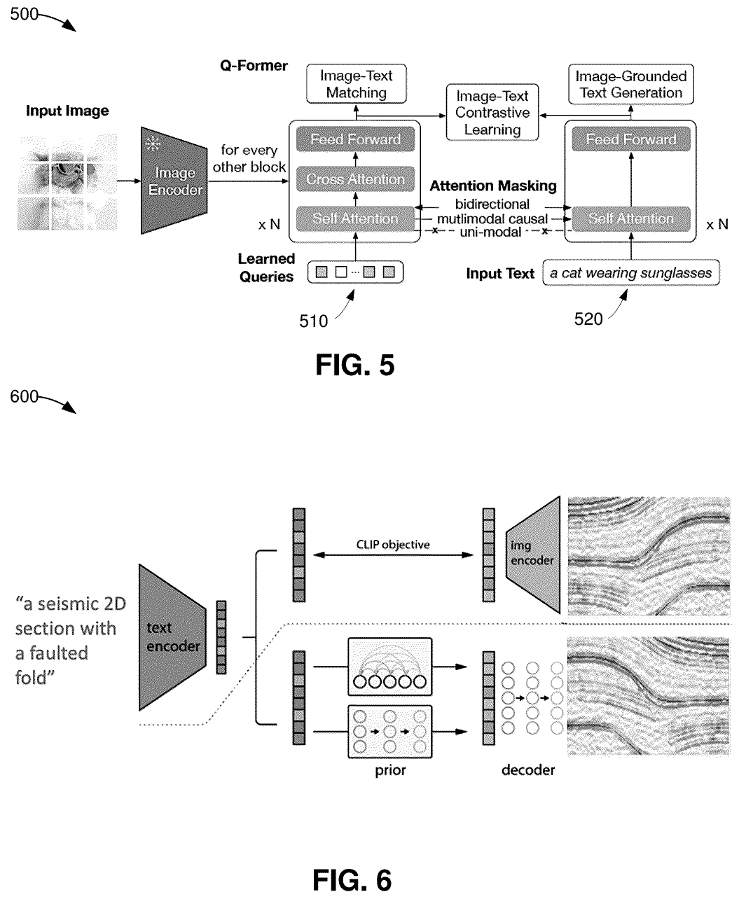

It is noted that some ML architectures have proven the use of image-to-text use cases, including captioning, VQA, and other language vision assistance, like Flamingo, Llava, and BLIP. However, embodiments of the subsurface system can use any of these models trained, or fine-tuned, on subsurface datasets. In some embodiments, a subsurface system trains a model called BLIP-2, which is an advanced model proposed for language vision assistance that incorporates several enhancements to improve upon its predecessor, the BLIP model. The BLIP-2 model uses a two-stream architecture where one stream processes the image, such as an image encoder, and the other processes the question, such as a large language model (LLM). These two fixed streams of models are then fused to combine the features from the visual and textual inputs using a proposed fusion mechanism, named Q-former 500, which is shown as a block representation in FIG. 5.

In accordance with various embodiments, the Q-former 500 has an image transformer 510 and a text transformer 520. The image transformer 510 may interact with the frozen image encoder for visual feature extraction. A fixed number of “learnable” queries are given as input to this transformer 410. These queries interact with each other through the self-attention layers and interact with the image features through the cross-attention layer, as shown. These queries can also interact with the text simply by sending a concatenation of the learnable queries and text tokens to the self-attention layer.

The text transformer 520 acts as both the text decoder and text encoder. The text input to this model can also interact with the learnable queries in the same way mentioned above. Hence, both the submodules share the self-attention layers. The Q-former 500 may be trained on a range of objectives, such as image-text contrastive learning, image-grounded text generation, and image-text matching. For instance, image-text contrastive learning may help in maximizing the mutual information gained from the image and the text features by contrasting the image-text similarity of the positive pairs against the negative pairs. For image-grounded text generation, only the self-attention layer allows the interaction between the learnable image queries and the encoded text. Hence, to perform this task, the learnable queries are forced to extract the visual features from the image features provided by the frozen image encoder. These visual features also capture the information about the text.

Embodiments of the Q-former 500 may additionally provide image-text matching in which the model is required to perform a binary classification and tell us whether an image-text pair is a positive or a negative pair. As conveyed in FIG. 5, in the generative pre-training stage, the Q-Former 500 connects the image encoder to the LLM, which allows the output query embeddings to be prepended to the input text embeddings, functioning as soft visual prompts that condition the LLM on visual representation extracted by the Q-Former 500. Since output embeddings are limited, this also serves as an information bottleneck that feeds only the most useful information to the LLM while removing any irrelevant information. As such, the burden of the LLM on learning vision-language alignment is reduced, thus mitigating the catastrophic forgetting problem.

Similar to image-to-text, some ML architectures may be trained for this task, including Stable Diffusion or Delle-E(2,3). The model implemented in some embodiments is called unCLIP (DALLE-2) 600, which illustrated in FIG. 6. The model consists of CLIP prior, and decoder. CLIP consists of a text encoder and an image encoder, which is designed to efficiently learn visual concepts from natural language supervision. Prior is a diffusion model with transformer architecture that can convert text embedding to image embedding. Decoder is a Denoising Diffusion Implicit Model (DDIM) with U-Net architecture, which can sample images conditioned on image embeddings. After training CLIP, prior, and decoder separately. We combine text encoder from the trained CLIP, prior, and decoder for inference. A new prompt or text will be converted to text embedding by the CLIP text encoder. Then, the prior will generate image embedding using text embedding. Finally, the decoder will sample images conditioned on image embeddings.

In order to provide an efficient and accurate subsurface system, sufficient data for training such a model is collected. Such collected data must consist of subsurface images (models) and corresponding text (captions, descriptions, question-answers, etc.). To generate text-model pairs for training in a subsurface system, embodiments employ the open-source PyNoddy tool, which is a kinematic forward modeling tool that generates structurally complex geological models in a stochastic and probabilistic manner. By generating a synthetic dataset comprising kinematically consistent geologic two-dimensional models and further seismic models with classes like fault, fold, tilt, frequency, and noise, assorted captions may be prepared using Monte Carlo sampling to describe features in the corresponding geological models and seismic data. It is contemplated that real subsurface data and more sophisticated synthetic models may be used for training of a subsurface system.

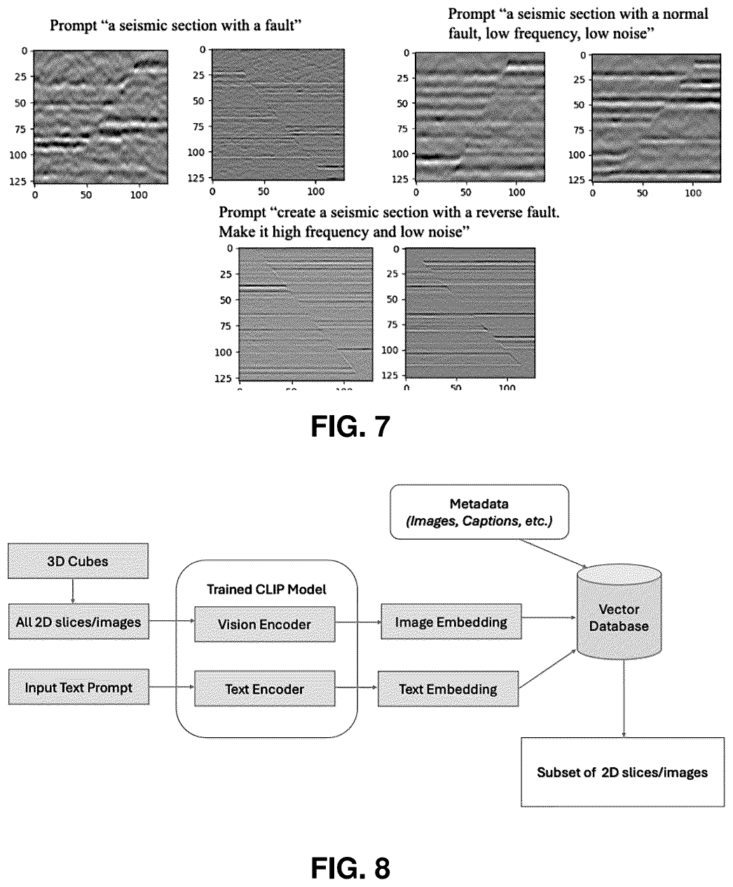

As discussed, a subsurface system trains machine-learning models to generate subsurface data with a text prompt, generate textual information from images, and combine these components in one system. In some embodiments, a subsurface system can be used to generate simple seismic and geologic two-dimensional models with a text prompt, as shown in FIG. 7, and retrieve seismic sections with a requested geological feature from seismic three-dimensional cubes, as shown in FIG. 8.

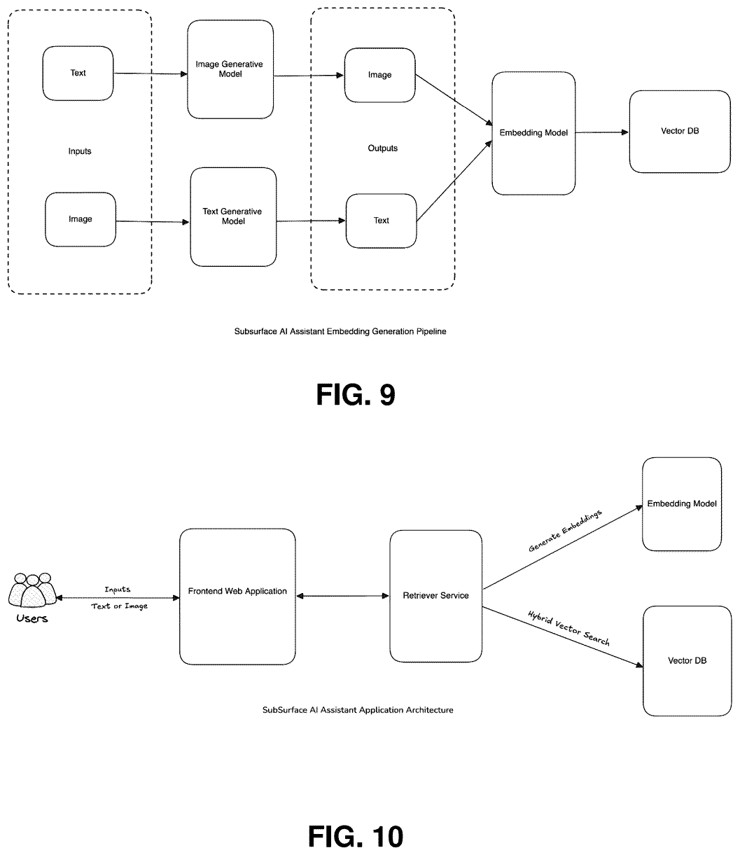

Various embodiments of an AI powered subsurface system initially operates for data acquisition and curation before embeddings pipeline are conducted, which enables subsurface AI assistant application. For data acquisition and curation, relatively large amounts of quality data are gathered, which forms the basis for effective AI model and systems development. For instance, subsurface domain specific data collection, or synthetic data generation, is conducted before preprocessing and cleaning of the data, such as handling missing data or inconsistencies. The data may then be formatted AI models, such as labelling or categorization of data. FIG. 9 generally illustrates embeddings pipeline flow while FIG. 10 illustrates an example subsurface system architecture.

### Exemplary Method

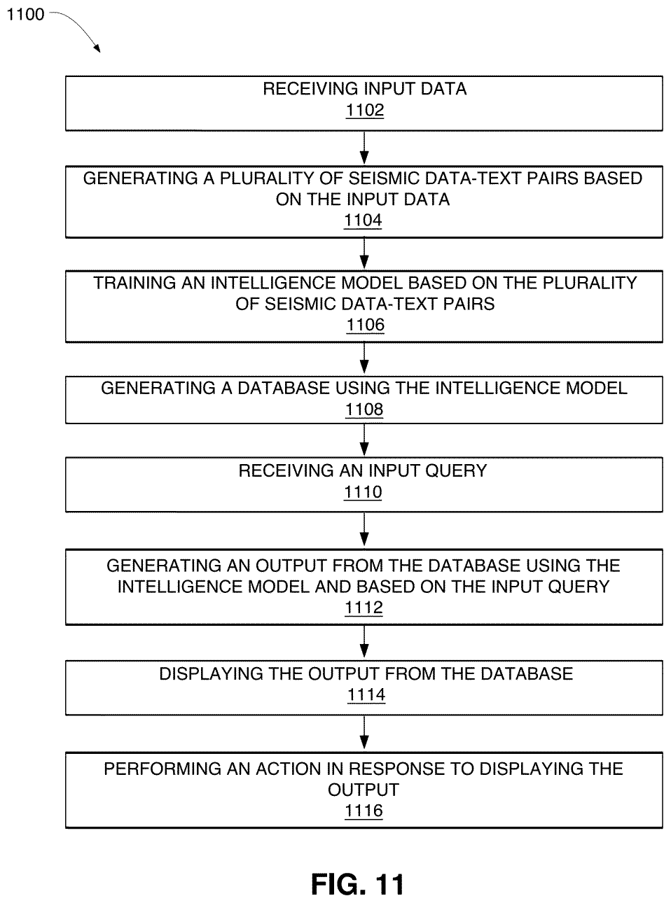

FIG. 11 illustrates a flowchart of a method 1100 for search and retrieval of subsurface data of a geological region, according to an embodiment. An illustrative order of the method 1100 is provided below; however, one or more portions of the method 1100 may be performed in a different order, simultaneously, repeated, or omitted. At least a portion of the method 1100 may be performed using a computing system.

The method 1100 may include receiving input data, as at 1102. The input data may include one or more of accumulated data related to the geological region, a dataset, or any combination thereof. The dataset may include one or more datasets related to the geological region. The accumulated data may include one or more of real seismic data, respective descriptions of the real seismic data, or a combination thereof. In at least one embodiment, the input data may also include one or more user defined inputs. The user defined inputs may be or include, but are not limited to, one or more of geological features, seismic features, a respective location of the geological features, a respective location of the seismic features, a temporal order of the geological features and/or the seismic features, or a combination thereof.

The method 1100 may also include generating a plurality of seismic data-text pairs based on the input data, as at 1104. Each seismic data-text pair of the plurality of seismic data-text pairs may include seismic data and generated text associated with the seismic data. The seismic data may include the real seismic data (e.g., the input data), synthetic seismic data, or a combination thereof.

Generating the plurality of seismic data-text pairs 1104 may include generating the seismic data based on the input data. The seismic data may include synthetic seismic data, real seismic data, or a combination thereof. The synthetic seismic data may be based on user defined inputs, such as the user defined inputs of the input data. The synthetic seismic data may be generated via one or more simulations based on the input data or the user defined inputs thereof. The user defined inputs may include one or more of geological features, seismic features, a respective location of the geological features, a respective location of the seismic features, a temporal order of the geological features and/or the seismic features, or the like, or a combination thereof. The synthetic seismic data may include synthetic seismic images, annotations of the synthetic seismic images, seismic features (e.g., faults, horizons, channels, etc.), or the like, or a combination thereof. The synthetic seismic images and the annotations of the synthetic seismic images may be generated simultaneously. The synthetic seismic images may include processed seismic images, post-stack seismic images, or the like, or a combination thereof. The real seismic data may include real seismic images, annotations of the real seismic image, or the like, or a combination thereof. The real seismic images may include processed real seismic images, post-stack real seismic images, or the like, or a combination thereof. The real seismic images may be from land, off-shore, or a combination thereof. The annotations of the real seismic images may be from a domain expert, an artificial intelligence (AI) agent, an AI system, AI software, or the like, or a combination thereof.

Generating the plurality of seismic data-text pairs 1104 may also include producing the generated texts for each seismic data-text pair of the plurality of seismic data-text pairs using a text large language model (LLM) and/or input from a domain expert and based on the input data. The input from the domain expert may include prompts from the domain expert, a word bank, case studies, databases, literature, reports, or the like, or a combination thereof. In one example, the generated texts may be generated based on public information or information available in the public domain. The text LLM may produce the generated texts based on the synthetic seismic data and the annotation of the synthetic seismic data. The text LLM may also produce the generated texts based on the real seismic data and the annotation of the real seismic data. Generating the plurality of seismic data-text pairs 1104 may further include generating the plurality of seismic data-text pairs based on the seismic data and the generated texts. For example, generating the plurality of seismic data-text pairs 1104 may include associating or otherwise linking the seismic data and the generated text with one another, such as via a relationship therebetween.

The method 1100 may also include training an intelligence model based on the plurality of seismic data-text pairs, as at 1106. The intelligence model may be trained based on the seismic data and the generated texts of the plurality of seismic data-text pairs. The intelligence model may be trained based on a relationship between the seismic data and the generated text for each seismic data-text pair of the plurality of seismic data-text pairs. The intelligence model may include an encoder/decoder, a trained encoder/decoder, or a combination thereof. The encoder/decoder may include one or more of a seismic data encoder/decoder, an image encoder/decoder, a text encoder/decoder, or a combination thereof.

Training the intelligence model 1106 may include training the encoder/decoder of the intelligence model to produce the trained encoder/decoder. The encoder/decoder may be trained based on the input data, the seismic data-text pairs or the seismic data thereof, additional seismic data, one or more examples of seismic data, one or more training sets, such as seismic training datasets, synthetic seismic data, real seismic data, or the like, or any combination thereof. Training the encoder/decoder may include training the image encoder/decoder to produce a trained image encoder/decoder. Training the encoder/decoder may also include training the text encoder/decoder to produce a trained text encoder/decoder. Training the encoder/decoder may further include training the seismic data encoder/decoder to produce a trained seismic data encoder/decoder. Training the seismic data encoder/decoder may include training a machine-learning (ML) model based on the seismic data using masked autoencoder learning approaches.

Training the intelligence model 1106 may also include determining and/or refining a relationship between the seismic data and the generated text for each seismic data-text pair of the plurality of seismic data-text pairs. Determining and/or refining the relationship may include determining one or more similarities between the seismic data and at least one of the generated texts. Determining and/or refining the relationship may also include determining one or more differences between the seismic data and at least one of the generated texts. Determining and/or refining the relationship may further include determining one or more mismatches between the seismic data and at least one of the generated texts. Determining and/or refining the relationship may also include determining one or more matches between the seismic data and at least one of the generated texts.

The method 1100 may also include generating a database using the intelligence model, as at 1108. The database may be generated using the trained encoder/decoder of the intelligence model. The database may be based on the plurality of seismic data-text pairs. For example, the database may be generated based on the relationship between the seismic data and the generated text for each seismic data-text pair of the plurality of seismic data-text pairs. The database may include a seismic database, an image database, a text database, or a combination thereof. In one example, the database may be based on one or more of the input data, the seismic data-text pairs or the seismic data thereof, additional seismic data, one or more examples of seismic data, one or more training sets, such as seismic training datasets, synthetic seismic data, real seismic data, or the like, or any combination thereof.

Generating the database 1108 may include processing the seismic data-text pairs or the seismic data thereof with the trained encoder/decoder to generate embeddings. The embeddings may be seismic data embeddings, image embeddings, text embeddings, or a combination thereof. Processing the seismic data-text pairs or the seismic data thereof with the trained encoder/decoder may include processing the seismic data-text pairs or the seismic data thereof with the trained seismic data encoder to generated seismic data embeddings. Processing the seismic data-text pairs or the seismic data thereof with the trained encoder/decoder may also include processing the seismic data-text pairs or the seismic data thereof with the trained image encoder to generate image embeddings. Processing the seismic data-text pairs or the seismic data thereof with the trained encoder/decoder may further include processing the seismic data-text pairs or the seismic data thereof with the trained text encoder to generate text embeddings. The embeddings, including the seismic data embeddings, the image embeddings, and/or the text embeddings may be stored in the database.

The method 1100 may include supplementing the database with additional input data. The additional input data may include metadata. The metadata may include additional seismic data and additional seismic data annotations. The additional seismic data annotations may be provided by domain expert.

The method 1100 may also include receiving an input query, as at 1110. The input query may include a seismic data query, a text query, an image query, or a combination thereof. The input query may be preprocessed.

The method 1100 may also include generating an output from the database using the intelligence model and based on the input query, as at 1112. Generating the output 1100 may include utilizing the trained encoder/decoder of the intelligence model. Generating the output 1100 may include processing the input query with the trained encoder/decoder to generate an input query embedding. Generating the output 1100 may also include determining a relationship between the input query embedding and the database. Generating the output 1100 from the database based on the relationship between the input query embedding and the database.

The method 1100 may also include displaying the output from the database, as at 1114. The method 1100 may further include performing an action in response to displaying the output, as at 1116. The action may include generating or transmitting a signal that recommends, instructs, or causes a physical action to occur. The physical action may include one or more of optimizing a trajectory of a wellbore drilling operation, conducting drilling operations, conducting an exploratory operation, utilizing the single-upscaled permeability model in a simulation model, designing a production strategy, designing a hydraulic fracturing strategy, conducting risk assessments, or any combination thereof.

### Exemplary Computing System

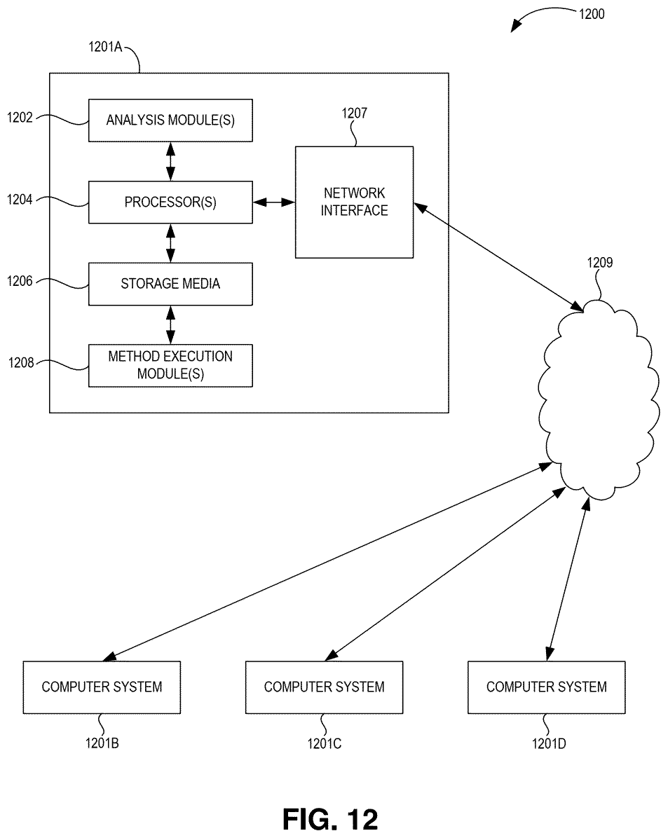

In some embodiments, the methods of the present disclosure may be executed by a computing system. FIG. 12 illustrates an example of such a computing system 1200, in accordance with some embodiments. The computing system 1200 may include a computer or computer system 1201A, which may be an individual computer system 1201A or an arrangement of distributed computer systems. The computer system 1201A includes one or more analysis modules 1202 that are configured to perform various tasks according to some embodiments, such as one or more methods disclosed herein. To perform these various tasks, the analysis module 1202 executes independently, or in coordination with, one or more processors 1204, which is (or are) connected to one or more storage media 1206. The processor(s) 1204 is (or are) also connected to a network interface 1207 to allow the computer system 1201A to communicate over a data network 1209 with one or more additional computer systems and/or computing systems, such as 1201B, 1201C, and/or 1201D (note that computer systems 1201B, 1201C and/or 1201D may or may not share the same architecture as computer system 1201A, and may be located in different physical locations, e.g., computer systems 1201A and 1201B may be located in a processing facility, while in communication with one or more computer systems such as 1201C and/or 1201D that are located in one or more data centers, and/or located in varying countries on different continents).

A processor may include a microprocessor, microcontroller, processor module or subsystem, programmable integrated circuit, programmable gate array, or another control or computing device.

The storage media 1206 may be implemented as one or more computer-readable or machine-readable storage media. Note that while in the example embodiment of FIG. 12 storage media 1206 is depicted as within computer system 1201A, in some embodiments, storage media 1206 may be distributed within and/or across multiple internal and/or external enclosures of computing system 1201A and/or additional computing systems. Storage media 1206 may include one or more different forms of memory including semiconductor memory devices such as dynamic or static random access memories (DRAMs or SRAMs), erasable and programmable read-only memories (EPROMs), electrically erasable and programmable read-only memories (EEPROMs) and flash memories, magnetic disks such as fixed, floppy and removable disks, other magnetic media including tape, optical media such as compact disks (CDs) or digital video disks (DVDs), BLURAY^{®}disks, or other types of optical storage, or other types of storage devices. Note that the instructions discussed above may be provided on one computer-readable or machine-readable storage medium, or may be provided on multiple computer-readable or machine-readable storage media distributed in a large system having possibly plural nodes. Such computer-readable or machine-readable storage medium or media is (are) considered to be part of an article (or article of manufacture). An article or article of manufacture may refer to any manufactured single component or multiple components. The storage medium or media may be located either in the machine running the machine-readable instructions, or located at a remote site from which machine-readable instructions may be downloaded over a network for execution.

In some embodiments, computing system 1200 contains one or more method execution module(s) 1208. In the example of computing system 1200, computer system 1201A includes the method execution module 1208. In some embodiments, a single method execution module may be used to perform some aspects of one or more embodiments of the methods disclosed herein. In other embodiments, a plurality of method execution modules may be used to perform some aspects of methods herein.

It should be appreciated that computing system 1200 is merely one example of a computing system, and that computing system 1200 may have more or fewer components than shown, may combine additional components not depicted in the example embodiment of FIG. 12, and/or computing system 1200 may have a different configuration or arrangement of the components depicted in FIG. 12. The various components shown in FIG. 12 may be implemented in hardware, software, or a combination of both hardware and software, including one or more signal processing and/or application specific integrated circuits.

Further, the steps in the processing methods described herein may be implemented by running one or more functional modules in information processing apparatus such as general purpose processors or application specific chips, such as ASICs, FPGAs, PLDs, or other appropriate devices. These modules, combinations of these modules, and/or their combination with general hardware are included within the scope of the present disclosure.

Computational interpretations, models, and/or other interpretation aids may be refined in an iterative fashion; this concept is applicable to the methods discussed herein. This may include use of feedback loops executed on an algorithmic basis, such as at a computing device (e.g., computing system 1200, FIG. 12), and/or through manual control by a user who may make determinations regarding whether a given step, action, template, model, or set of curves has become sufficiently accurate for the evaluation of the subsurface three-dimensional geologic formation under consideration.

The foregoing description, for purpose of explanation, has been described with reference to specific embodiments. However, the illustrative discussions above are not intended to be exhaustive or limiting to the precise forms disclosed. Many modifications and variations are possible in view of the above teachings. Moreover, the order in which the elements of the methods described herein are illustrated and described may be re-arranged, and/or two or more elements may occur simultaneously. The embodiments were chosen and described in order to best explain the principles of the disclosure and its practical applications, to thereby enable others skilled in the art to best utilize the disclosed embodiments and various embodiments with various modifications as are suited to the particular use contemplated.

What is claimed is:

1. A method for search and retrieval of subsurface data of a geological region, the method comprising:
receiving input data related to the geological region;
generating a plurality of seismic data-text pairs based on the input data;
training an intelligence model based on the plurality of seismic data-text pairs;
generating a database using the intelligence model;
receiving an input query comprising a seismic data query, a text query, an image query, or a combination thereof; and
generating an output from the database using the intelligence model and based on the input query.

2. The method of claim 1, wherein each seismic data-text pair of the plurality of seismic data-text pairs comprises seismic data and generated text associated with the seismic data.

3. The method of claim 2, wherein generating the plurality of seismic data-text pairs comprises generating the seismic data for each seismic data-text pair of the plurality of seismic data-text pairs based on the input data, wherein the seismic data comprises synthetic seismic data, real seismic data, or a combination thereof.

4. The method of claim 3, wherein the synthetic seismic data is generated using a simulation based on user defined inputs, and wherein the synthetic seismic data comprises synthetic seismic images, annotations of the synthetic seismic images, seismic features, or a combination thereof.

5. The method of claim 4, wherein the synthetic seismic data comprises the synthetic seismic images and the annotations of the synthetic seismic images, and wherein the synthetic seismic images and the annotations of the synthetic seismic images are generated simultaneously.

6. The method of claim 3, wherein the real seismic data comprises real seismic images, annotations of the real seismic image, or a combination thereof.

7. The method of claim 2, wherein generating the plurality of seismic data-text pairs comprises generating the generated text for each seismic data-text pair of the plurality of seismic data-text pairs based on the input data and using a text large language model (LLM), input from a domain expert, or a combination thereof.

8. The method of claim 2, wherein the intelligence model is trained based on a relationship between the respective seismic data and the respective generated text for each seismic data-text pair of the plurality of seismic data-text pairs, and wherein training the intelligence model comprises training an encoder/decoder of the intelligence model based on the plurality of seismic data-text pairs to produce a trained encoder/decoder.

9. The method of claim 8, wherein the database is generated using the trained encoder/decoder of the intelligence model.

10. The method of claim 1, further comprising:
displaying the output from the database; and
performing an action in response to displaying the output, wherein the action comprises generating or transmitting a signal that recommends, instructs, or causes a physical action to occur, wherein the physical action comprises one or more of optimizing a trajectory of a wellbore drilling operation, conducting drilling operations, conducting an exploratory operation, utilizing a single-upscaled permeability model in a simulation model, designing a production strategy, designing a hydraulic fracturing strategy, conducting risk assessments, or any combination thereof.

11. A computing system, comprising:
one or more processors; and
a memory system comprising one or more non-transitory computer-readable media storing instructions that, when executed by at least one of the one or more processors, cause the computing system to perform operations for search and retrieval of subsurface data of a geological region, the operations comprising:
receiving input data comprising accumulated data related to the geological region;
generating a plurality of seismic data-text pairs based on the input data, wherein each seismic data-text pair of the plurality of seismic data-text pairs comprises seismic data and generated text associated with the seismic data;
training an intelligence model based on a relationship between the respective seismic data and the respective generated text for each seismic data-text pair of the plurality of seismic data-text pairs;
generating a database using the intelligence model;
receiving an input query comprising a seismic data query, a text query, an image query, or a combination thereof; and
generating an output from the database using the intelligence model and based on the input query.

12. The computing system of claim 11, wherein generating the plurality of seismic data-text pairs comprises generating the seismic data for each seismic data-text pair of the plurality of seismic data-text pairs based on the input data, wherein the seismic data comprises synthetic seismic data, real seismic data, or a combination thereof, and wherein the synthetic seismic data is generated using a simulation based on user defined inputs.

13. The computing system of claim 12, wherein:
the synthetic seismic data comprises synthetic seismic images and annotations of the synthetic seismic images that are generated simultaneously;
the real seismic data comprises real seismic images and annotations of the real seismic image;
wherein generating the plurality of seismic data-text pairs comprises generating the generated text for each seismic data-text pair of the plurality of seismic data-text pairs using a text large language model (LLM) and based on the synthetic seismic data, the annotation of the synthetic seismic data, the real seismic data, and the annotation of the real seismic data;
training the intelligence model comprises training an encoder/decoder of the intelligence model based on the plurality of seismic data-text pairs to produce a trained encoder/decoder.

14. The computing system of claim 13, wherein the database is generated using the trained encoder/decoder of the intelligence model.

15. The computing system of claim 14, wherein generating the output comprises:
processing the input query with the trained encoder/decoder to generate an input query embedding;
determining a relationship between the input query embedding and the database; and
generating the output from the database based on the relationship between the input query embedding and the database.

16. A non-transitory computer-readable medium storing instructions that, when executed by one or more processors of a computing system, cause the computing system to perform operations for search and retrieval of subsurface data or a geological region, the operations comprising:
receiving input data comprising accumulated data related to the geological region;
generating a plurality of seismic data-text pairs based on the input data, wherein each seismic data-text pair of the plurality of seismic data-text pairs comprises seismic data and generated text associated with the seismic data, wherein generating the plurality of seismic data-text pairs comprises generating the seismic data for each seismic data-text pair of the plurality of seismic data-text pairs based on the input data, wherein the seismic data comprises synthetic seismic data, real seismic data, or a combination thereof, and wherein the synthetic seismic data is generated using a simulation based on user defined inputs;
training an intelligence model based on the plurality of seismic data-text pairs, wherein training the intelligence model comprises training an encoder/decoder of the intelligence model based on the plurality of seismic data-text pairs to produce a trained encoder/decoder;
generating a database using the trained encoder/decoder of the intelligence model;
receiving an input query comprising a seismic data query, a text query, an image query, or a combination thereof; and
generating an output from the database using the trained encoder/decoder of the intelligence model and based on the input query.

17. The non-transitory computer-readable medium of claim 16, wherein:
the synthetic seismic data comprises synthetic seismic images and annotations of the synthetic seismic images that are generated simultaneously;
the real seismic data comprises real seismic images and annotations of the real seismic image;
generating the plurality of seismic data-text pairs comprises generating the generated text for each seismic data-text pair of the plurality of seismic data-text pairs using a text large language model (LLM) and based on the synthetic seismic data, the annotation of the synthetic seismic data, the real seismic data, and the annotation of the real seismic data; and
the intelligence model is trained based on a relationship between the respective seismic data and the respective generated text for each seismic data-text pair of the plurality of seismic data-text pairs.

18. The non-transitory computer-readable medium of claim 16, wherein generating the output comprises:
processing the input query with the trained encoder/decoder to generate an input query embedding;
determining a relationship between the input query embedding and the database; and
generating the output from the database based on the relationship between the input query embedding and the database.

19. The non-transitory computer-readable medium of claim 16, wherein training the encoder/decoder of the intelligence model comprises:
training an image encoder/decoder of the intelligence model to produce a trained image encoder/decoder;
training a text encoder/decoder of the intelligence model to produce a trained text encoder/decoder; and
training a seismic data encoder/decoder of the intelligence model to produce a trained seismic data encoder/decoder.

20. The non-transitory computer-readable medium of claim 16, further comprising supplementing the database with additional input data, wherein the additional input data comprises metadata, and wherein the metadata comprises additional seismic data and additional seismic data annotations, wherein the additional seismic data annotations are provided by a domain expert.
